(19) United States
(12) Patent Application Publication
(10) Pub. No.: US 2025/0354863 A1
(43) Pub. Date: Nov. 20, 2025

(54) AVALANCHE DIODE ARRANGEMENT, ELECTRONIC DEVICE AND METHOD FOR CONTROLLING AN AVALANCHE DIODE ARRANGEMENT

(71) Applicant: ams International AG, Jona (CH)

(72) Inventors: Robert KAPPEL, Wettmannstätten (AT); Gerhard LOSINSCHEK, Premstätten (AT); Georg RÖHRER, Lebring - Sankt Margarethen (AT); Sargis ABOVYAN, Graz (AT)

(21) Appl. No.: 18/993,439

(22) PCT Filed: Jun. 20, 2023
(86) PCT No.: PCT/EP2023/066626

§ 371 Date: Jan. 10, 2025

(30) Foreign Application Priority Data
Jul. 15, 2022 (DE) 10 2022 117 761.0

(51) Int. Cl. G01J 1/44

(52) U.S. Cl. CPC G01J 1/44; G01J 2001/444; G01J 2001/4466

(57) ABSTRACT

An avalanche diode arrangement includes a three-dimensional integrated circuit including a stack with at least a top-tier and a bottom-tier. The avalanche diode arrangement also includes a breakdown voltage monitor circuit. The top-tier includes an array of avalanche diodes. The bottom-tier includes an array of integrated light sources, located below the top-tier. In a calibration mode of operation, the light sources are operable to emit light towards the avalanche diodes. The breakdown voltage monitor circuit is operable to adjust bias voltages of the avalanche diodes depending on trigger events induced by light emitted by the light sources during the calibration mode of operation.

This disclosure relates to an avalanche diode arrangement, an electronic device and a method for controlling an avalanche diode arrangement.

### BACKGROUND

Single Photon Avalanche Diodes (SPAD hereinafter) are extremely fast and sensitive optical sensors and are used in a wide area of applications: as imaging sensors, in optical tomography, time-of-flight etc. The SPAD sensor is a reverse biased device operating at a supply voltage VHV higher than the breakdown voltage VBD. The difference between the bias and the breakdown voltage of the SPAD is called excess bias voltage VEX. SPADs are operated above their breakdown voltage at a constant excess bias voltage. Since the breakdown voltage of a SPAD device vary with process variation and temperature, electronic devices which rely on SPAD technology, such as direct time-of-flight systems, typically require a regulation loop to adjust the voltage across the SPAD device in order to keep the excess bias constant. This excess bias voltage defines the sensitivity and power consumption of a system such as a time-of-flight system.

Setting the voltage across the SPAD is therefore part of the setup procedure during production test and each startup in the field. The art has come up with solutions to monitor an excess bias voltage monitoring circuitry. Proposed solutions rely on dark count or external light sources to trigger SPAD events. Since the dark count can be very low (especially in case of low temperature) the observation window for a certain SPAD voltage need to be very long which extends the calibration time. Thus, an external light source is therefore necessary at the expense of fill factor and footprint, and ultimately cost.

It is an object of the present disclosure to provide an avalanche diode arrangement, an electronic device and a method for controlling an avalanche diode arrangement with a faster calibration and startup.

These objectives are achieved by the subject-matter of the independent claims. Further developments and embodiments are described in the dependent claims.

### SUMMARY

The following relates to an improved concept in the field of optical sensors, in particular avalanche diodes and single-photon avalanche diodes, SPADs. One aspect relates to using an integrated local light source to limit observation time during calibration, e.g. during start up. This can be achieved by adding a local light emitting pn-junction into a 3D integrated circuit which forms an avalanche diode arrangement. A breakdown voltage monitor circuit is suggested for monitoring an excess bias voltage VEX. Said circuit allows to estimate and adjust a bias voltage VHV as a function of light pulses emitted by the integrated local light source during a calibration process.

In at least one embodiment, an avalanche diode arrangement comprises a three-dimensional integrated circuit (or 3D-IC).

The 3D-IC comprises a stack with at least one top-tier and a bottom-tier. Furthermore, the arrangement comprises a breakdown voltage monitor circuit. The top-tier comprises an array of avalanche diodes and the bottom-tier comprises an array of integrated light sources. The light sources are located below the top-tier. Particularly, the top-tier and the bottom-tear are semiconductor layers.

The light sources are operable to emit light towards the avalanche diodes. The breakdown voltage monitor circuit is operable to adjust bias voltages of the avalanche diodes depending on trigger events induced by light emitted by the light sources during a calibration mode of operation. Particularly, the light sources emit light towards the avalanche diodes during operation. Particularly, the breakdown voltage monitor circuit is configured to adjust the bias voltages of the avalanche diodes depending on trigger events induced by light emitted by the light sources during a calibration mode of operation.

Particularly, the light sources emit light during operation, the light impinge on the avalanche diodes. Preferably, the SPADs cover the light sources at least partially, seen in plan view on the avalanche diode arrangement. For example, each light source is covered by one avalanche diode in plan view on the avalanche diode arrangement. For example, the light sources are pn-junctions within the bottom-tier.

The proposed concept allows fast calibration of operation voltage of the avalanche diode arrangement, e.g. a SPAD device, during startup test in dark environment (wafer sort). To date calibration relies on trigger events. In a dark environment, however, observation time for each voltage step needed to be long enough to have a high probability of occurrence of trigger events. This limitation of long observation time is solved by adding a local light emitting pn-junction acting as a “weak” LED. The integrated light sources are local in the sense that they are integrated into the bottom-tier of the 3D-IC. This way there is no need for external light sources, which would increase footprint and costs of the device. Instead, according to the proposed concept the fill factor and footprint are not impacted by the light sources due to 3D stacking.

A three-dimensional integrated circuit (or 3D-IC) denotes an integrated circuit which is manufactured by stacking wafers, such as silicon wafers, or dies and interconnecting them vertically (e.g. with respect to a surface normal of the stack). For example, a 3D-IC is manufactured by stacking silicon wafers or dies and interconnecting them vertically using, for instance, hybrid bonding, through-silicon vias (TSVs) or Cu-Cu connections using MOS (metal-oxide semiconductor) technology. The resulting 3D-IC behaves is a single device or a single chip to achieve performance improvements at reduced power and smaller footprint than conventional two dimensional processes.

The terms top-tier and bottom-tier denote wafers or dies that are stacked to form the 3D-IC. The orientation indicated by “top” or “bottom” may be arbitrary and be subject to design choice. For example, the top-tier comprising the array of avalanche diodes may be top in the sense that, with respect to a surface normal of the stack, it is the tier that is arranged to receive incident light. Particularly, the top-tier and the bottom-tier are mechanically stable connected to each other. Preferably, main surfaces of the top-tier and the bottom-tier run parallel to each other. Further, outer main surfaces of the avalanche diode arrangement are preferably formed by main surfaces of the top-tier and the bottom-tier.

The light sources are located below the top-tier so that optical paths are established which optically connect the light sources with the avalanche diodes from the array. The light travels through the bottom-tier towards the top-tier. For example, the top-tier and the bottom-tier are based on a substrate material, such as silicon. The substrate material may be, at least to some extent, transparent to the light emitted by the light sources. In the case of silicon there is a noticeable window for infrared light. Particularly, silicon transmits infrared light to some extend. Thus, the light sources may be arranged to emit infrared light, which may only be absorbed and scattered to a degree that allows a portion of light to reach the avalanche diodes from the array. This portion may be “weak” but can be sufficient to increase the probability of occurrence of trigger events induced by the light emitted by the light sources during the calibration mode of operation, despite dark environment.

In at least one embodiment, the avalanche diodes are implemented as single-photon avalanche diodes, SPADs. SPADS are semiconductor devices, which are based on a pn-junction. The pn-junction is reverse-biased at an operating voltage that exceeds the pn-junction's breakdown voltage. The bias voltage of the SPADs is adjusted by means of the breakdown voltage monitor circuit. For example, adjusting starts with a certain level of excess bias voltage and is reduced depending on the trigger events induced by light emitted by the light sources during the calibration mode of operation. This allows to efficiently account for production differences, for example.

In at least one embodiment, the array of integrated light sources comprises pn-junctions implemented in a bottom substrate of the bottom-tier. Basically, the light sources are implemented as light emitting diodes integrated in the substrate of the bottom-tier. Said light emitting diodes can be driven with forward currents to emit light towards the array in the top-tier.

In at least one embodiment, the pn-junctions form an n+-doped region to p-well diode within a deep n-well. The diodes can be manufactured by means of semiconductor wafer-level technology, such as CMOS.

Particularly, the pn-junctions of the light sources are formed by the n+-doped regions in direct contact to the p-wells. Particularly, the n+-doped region is a n-doped semiconductor region with a n-dopand concentration of at least 10¹⁸ cm⁻³, while the p-well is a p-doped semiconductor region. For example, the n+-doped region is a semiconductor layer with a n-dopand concentration of at least 10¹⁸ cm⁻³. Particularly, the pn-junctions formed by the n+-doped region in direct contact to the p-well are inserted in the deep n-well.

In at least one embodiment, the pn-junctions comprise a light emitting area free of a conducting layer, such as silicidation blocked in the n+-doped region with the exception of contacts. The light emitting area allows light to be emitted by the light emitting diode, which would else be blocked by the conducting layer, such as silicide.

Particularly, the light emitting area is at least partially free of a silicide layer comprising or consisting of the silicide.

In at least one embodiment, the bottom-tier comprises a sensor logic, e.g., including readout electronics. Alternatively, the sensor logic can be arranged in the top-tier at least in parts.

In at least one embodiment, the sensor logic further comprises at least one driver circuit to provide, in the calibration mode of operation, respective forward currents to the light sources of the array of integrated light sources. The driver circuit may be controlled such that integrated light sources emit light during the calibration mode of operation. For example, control may be issued by a control unit, such as a digital system control. Furthermore, the driver circuit may be synchronized in operation with the breakdown voltage monitor circuit.

In at least one embodiment, the driver circuit comprises programmable current sources to provide the forward currents. The forward currents may be programmed in intensity or in a timing sequence, e.g. when during the calibration mode of operation a current source is activated to provide forward current to a respective light source.

In at least one embodiment, the top-tier and the bottom-tier are electrically interconnected, e.g., by way of hybrid bonding. This way, the top-tier and the bottom-tier can be stacked. For example, the top-tier and the bottom-tier can be manufactured at wafer level. A SPAD wafer can be optimized independently from a CMOS wafer. A fill factor of the array, e.g. a SPAD array, is limited by SPADs only and not by a CMOS process and allows for back side illuminated SPADs.

In at least one embodiment, the avalanche diodes form groups in the top-tier and one light source is dedicated for each group of avalanche diodes. Emission of light towards the avalanche diodes typically undergoes a series of scattering events due to the substrate material. Thus, light may not be directly emitted towards only a single light source. Thus, it may suffice to arrange one light source for a group of avalanche diodes.

In at least one embodiment, the avalanche diodes are arranged in a top substrate of the top-tier, so as to form a backside illuminated array and the top-tier is flipped so that an active surface of the avalanche diodes faces the bottom-tier. This design may increase the amount of light received by the SPAD from the light source.

In at least one embodiment, metallization layers are arranged in the top-tier and/or bottom-tier so as to guide light emitted by the light sources towards the avalanche diodes. The metallization layers may have optical properties in the sense that light is more directly guided towards the avalanche diodes. The metallization layers may be grouped in the substrate to limit the possible optical paths towards the avalanche diodes. Furthermore, the metallization layers can be arranged with reflective layers or low absorbing coating to increase light guided towards the avalanche diodes.

In at least one embodiment, the breakdown voltage monitor circuit comprises at least one quenching circuit for quenching of an avalanche current, at least one comparator block with two fast comparators for estimating an excess bias voltage depending on the avalanche current, and at least one digital logic to provide output signals to adjust a bias voltage based on the estimate of voltage divider.

In at least one embodiment, the sensor logic comprises a charge pump for generating the bias voltage for the avalanche diodes, respectively. Furthermore, a digital system control (DSC) is operable for implementing a monitoring algorithm to operate the breakdown voltage monitor circuit in the calibration mode of operation. A monitoring algorithm may be implemented based on the method for controlling an avalanche diode arrangement, for example. Particularly, the digital system control implements a monitoring algorithm to operate the breakdown voltage monitor circuit in the calibration mode of operation.

In at least one embodiment, the digital system control is operable to control the driver circuit, such that the driver circuit activates the current sources to drive the light sources, to emit light towards the avalanche diodes in the top-tier. Particularly, the digital system control is configured to control the driver circuit.

In at least one embodiment, an electronic device comprises a host system and at least one avalanche diode arrangement according to one more of the aspects discussed above. The host system may include any electronic system, which comprises an optical sensor. Examples include: all direct time of flight products, mobile phones, smart glasses, autonomous driving systems, to name but a few. Applications include 3D imaging, LDAF, Augmented Reality, LIDAR, etc.

Furthermore, a method for controlling an avalanche diode arrangement is suggested. The method, in a calibration mode of operation, comprises the step of using one or more light sources arranged in a bottom-tier of a stack forming a three-dimensional integrated circuit, to emit light towards an array of avalanche diodes, which are arranged in a top-tier of the stack. In a next step, bias voltages of the avalanche diodes are adjusted depending on trigger events induced by light emitted by the light sources during a calibration mode of operation.

Further embodiments of the method become apparent to the skilled reader from the aforementioned embodiments of the avalanche diode arrangement and the electronic device, and vice-versa.

### BRIEF DESCRIPTION OF THE DRAWINGS

The following description of figures may further illustrate and explain aspects of the avalanche diode arrangement, the electronic device and the method of controlling an avalanche diode arrangement. Components and parts of the avalanche diode arrangement that are functionally identical or have an identical effect are denoted by identical reference symbols.

Identical or effectively identical components and parts might be described only with respect to the figures where they occur first. Their description is not necessarily repeated in successive figures.

In the figures:

FIG. 1 shows an example embodiment of an avalanche diode arrangement,

FIG. 2 shows another example embodiment of an avalanche diode arrangement,

FIG. 3 shows an example embodiment of a sensor logic,

FIG. 4 shows an example scheme of a calibration mode of operation, and

FIGS. 5A and 5B show an example layout of an integrated light source.

### DETAILED DESCRIPTION

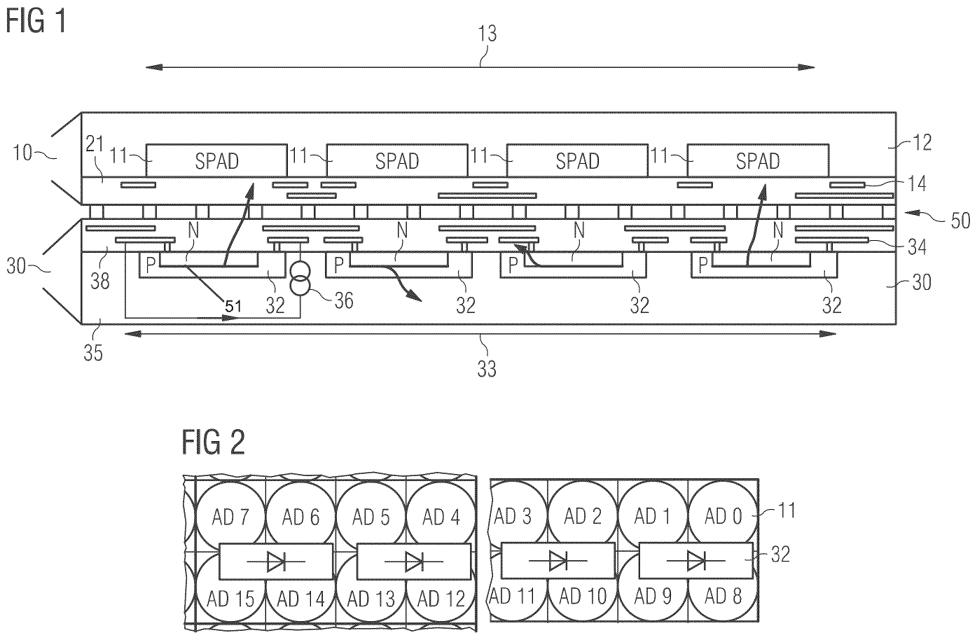

FIG. 1 shows an example embodiment of an avalanche diode arrangement. The drawing shows a cross-section of a three-dimensional integrated circuit (or 3D-IC) which forms the avalanche diode arrangement. The 3D-IC comprises a top-tier 10 and a bottom-tier 30. The terms top-tier wafer and top-tier as well as the terms bottom-tier wafer and bottom-tier can be used interchangeably, however. The two tiers are electrically interconnected by means of hybrid bonding 50.

The top-tier 10 comprises a substrate 12 and a backend of line dielectrics, BEOL, stack 21. Avalanche diodes 11 are arranged in the top substrate 12 to form a backside illuminated array of avalanche diodes 13. The top-tier 10 is flipped and connected to the bottom-tier wafer by the hybrid bonding 50. Furthermore, the top-tier 10 comprises metallization layers 14 to provide electrical interconnection between the tiers and/or to the avalanche diodes 11 and the array, e.g. arranged in BEOL (backend of line dielectrics). The top-tier 10 may comprise further electronic components which are not shown in the drawing, e.g. input/output terminals, etc. In this example, the avalanche diodes 11 are implemented as SPADs.

The bottom-tier 30 comprises a bottom substrate 35 and a backend of line dielectrics, BEOL, stack 38. Furthermore, the bottom-tier 30 comprises a sensor logic (not shown) 31, e.g. readout electronics. Furthermore, an array 33 of light sources 32 are integrated into the bottom substrate 35. In this example, the array 33 of light sources 32 is implemented as pn-junctions 32 in the bottom substrate 35 and are located below the top-tier 10, e.g. directly underneath avalanche diodes 11 from the array of avalanche diodes 13. The light sources 32 are electrically connected to driver circuits 36, which are arranged as part of the sensor logic 31. The driver circuits 36 comprise programmable current sources 37 to provide forward currents to the light sources 32 during a calibration mode of operation. Furthermore, the bottom-tier 30 comprises metallization layers 34 to provide electrical interconnection between the tiers and/or to the sensor logic 31, driver circuits 36 and light sources 32, etc. The metallization layers 14, 34 (e.g., of backend metal layers 21, 38 of the top and bottom-tier wafers) can be arranged so that there is no metal layer inbetween the pn-junctions 51 and the avalanche diodes 11, such as SPADs in order to provide optical paths from the bottom-tier light sources 32 to the array of avalanche diodes 13.

The sensor logic 31 further comprises a breakdown voltage monitor circuit 40, which is electrically connected to the avalanche diodes 11. The breakdown voltage monitor circuit 40 comprises a passive quenching circuit 41, a comparator block 42 with two fast comparators 43 and a digital logic 44. In this implementation the SPAD cathode is directly connected to the comparator 43 and there is a dedicated breakdown voltage monitor circuit 40 for each avalanche diode 11. Alternatively, at least parts of the breakdown voltage monitor circuit 40 may be shared, e.g. the digital logic 44. The breakdown voltage monitor circuit 40 is used to adjust the avalanche diodes reverse bias in order to eliminate excess bias voltage dependence.

Basically, during the calibration mode of operation the monitor circuit successively increases the voltage across the avalanche diodes 11 and senses an output of the diodes for a certain period of time. During a calibration sequence, the light sources 32, i.e. pn-junctions 51, become forward biased which results in on-chip generation of photons which, in turn, will trigger the avalanche diodes 11 of the top-tier 10. One aspect is, that due to the 3D stacking, the fill factor is not impacted by the pn-junctions 51.

FIG. 2 shows another example embodiment of an avalanche diode arrangement. The drawing shows a top-view of the three-dimensional integrated circuit (or 3D-IC) discussed with respect to FIG. 1. The top-tier 10 comprises avalanche diodes 11 which are arranged in a top substrate 12 to form a backside illuminated array of avalanche diodes 13. Depicted are 16 avalanche diodes 11 denoted AD0 to AD15. These diodes form groups of four avalanche diodes 11 (as indicated by rectangles in the drawing). In this example, there is one light source 32 arranged below the groups of four avalanche diodes 11. This ratio should only be considered as an example. Depending on the desired application there may be one light source 32 dedicated for each avalanche diode 11 in the top-tier 10, or any other number or ratio.

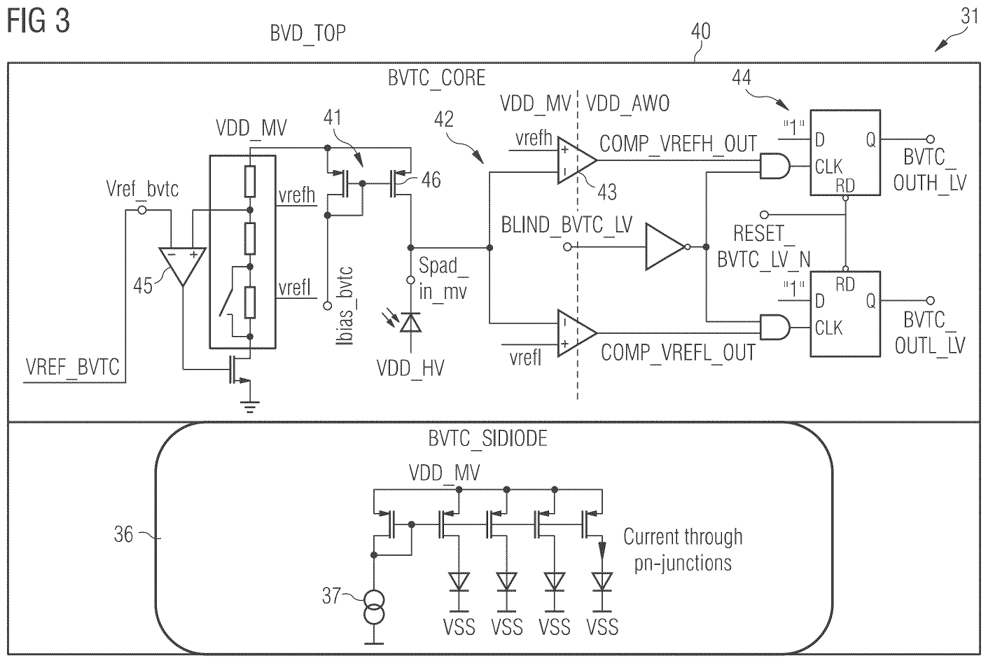

FIG. 3 shows an example embodiment of a sensor logic 31. The drawing shows an example embodiment of a breakdown voltage monitor circuit 40 and of a driver circuit 36. The breakdown voltage monitor circuit 40 comprises a passive quenching circuit 41, a comparator block 42 with two fast comparators 43 and a digital logic 44. The circuit as depicted is arranged for non-isolated SPADs (opposite polarity), for example.

The quenching circuit 41 provides a resistance in series with the avalanche diode 11, e.g. transistor 46 constitutes a quenching resistor. An avalanche current is induced as the SPAD receives incident light and self-quenches because it develops a characteristic voltage drop depending on the breakdown voltage VBD of the SPAD. After quenching of the avalanche current, the SPAD bias slowly recovers to the operating bias, and therefore the detector is ready to be ignited again. The breakdown voltage VBD is temperature dependent, and, thus, the dead time is different for different temperatures. The quenching circuit 41 is complemented with a control circuit 45, which generates the adjustable reference voltages connected to the window comparators (VREFH, VREFL). This allows to adjust an excess bias voltage VEX. Setting a dead time is not shown here. It can be done by adjusting the bias current that is sinking the current mirror 41. This control circuit 45 may be voltage or current controlled. Quenching resistance control together with the supply or bias voltage VHV calibration, allow for precise control of the dead time.

The comparator block 42 comprises two fast comparators 43, or window comparators. The comparators 43 compare a voltage with reference voltages VREFH and VREFL. If the excess bias voltage VEX is higher than VREFL and lower than VREFH, the bias voltage VHV voltage has an optimal value. The digital logic 44 comprises D-flip-flops. A BLIND signal gates the outputs of the two comparators 43 to the inputs of D-flip-flops during a reset phase.

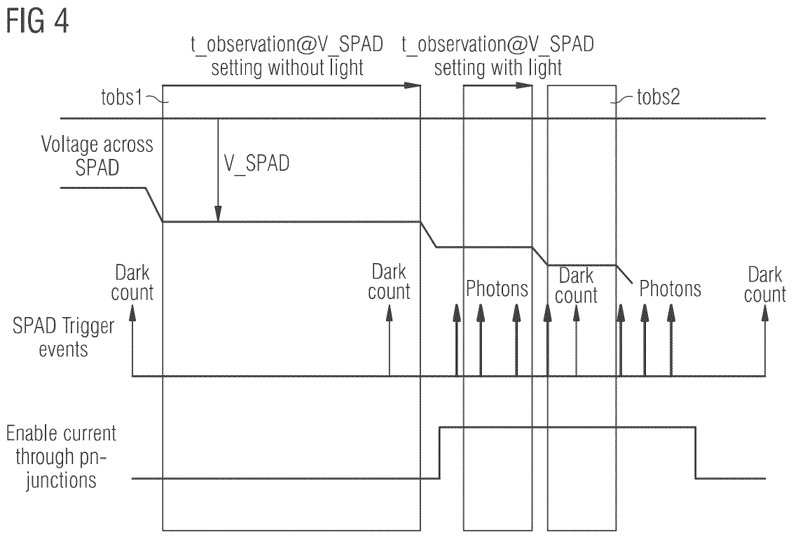

The sensor logic 31 typically comprises further electronic components such as a charge pump (not shown) for generating the bias voltage VHV (the array is supplied with the bias voltage) and a digital system control (DSC) for implementing a monitoring algorithm (discussed with respect to FIG. 4). Basically, the digital system control sets a reference voltage inside the breakdown voltage monitor circuit 40 by issuing a control signal. With different reference voltages, a different excess bias voltage VEX can be set. Depending on output signals OUTH and OUTL of the D-flip-flops the digital system control drives the charge pump to increase or decrease the bias voltage VHV. Further details of the breakdown voltage monitor circuit 40 have been disclosed in EP 3419168

Al and Lilic, Nenad, et al. “Excess Bias Voltage Monitoring Circuit.” 2018 IEEE 61st International Midwest Symposium on Circuits and Systems (MWSCAS). IEEE, 2018. Both publications are incorporated by reference.

The digital system control further controls the driver circuit 36. In turn, the driver circuit 36 activates the programmable current sources 37 to drive the light sources 32, e.g. pn-junctions 51, to emit light into the 3D-IC towards the avalanche diodes 11 in the top-tier 10. A supply current can be mirrored to the pn-junctions 51 by means of a current mirror.

FIG. 4 shows an example scheme of a calibration mode of operation. The plots show operation in a dark environment as a function of time. The top plot shows the voltage across a SPAD, which is successively increased in steps during the calibration mode. The middle plot shows trigger events, which can be caused by photons emitted by the light sources 32 or by dark count. The bottom plot indicates an enable control signal issued by the digital system control to the driver circuit 36. Said control signal defines periods of disabled light source and enabled light source.

The calibration mode of operation is entered by the digital system control (DSC). The mode comprises a first and a second phase, which define an observation period tobs1 without light and an observation period tobs2 with light. The phases are determined by the enable control signal issued by the digital system control to the driver circuit 36. Operation of the breakdown voltage monitor circuit 40 discussed in FIG. 3 relies on trigger events which allow to adjust the bias voltage VHV.

For example, in a low state of the enable control signal (first phase) the light sources 32 are turned off and the SPADs are only triggered by dark counts. Without an on-chip light source 32 as proposed, the number of trigger events is defined by the dark count rate of the SPADs. Two such dark counts are shown in the middle plot. Following the trigger events, the breakdown voltage monitor circuit 40 adjusts the different excess bias voltage VEX from an initial value. In this example, the negative bias voltage VHV is decreased in steps in order to increase the excess bias voltage VEX. The corresponding output signals OUTH and OUTL provide a measures whether the bias voltage VHV needs to be increased or decreased further. The plot shows that a time window for two successive dark counts to occur can be quite extended. Since the breakdown voltage monitor requires a SPAD event to check the voltage level a long observation time per step is required.

In case of an enabled on-chip light emitter, such as the light sources 32, the number of trigger events is significantly increased. In a high state of the enable control signal (second phase) the light sources 32 are turned on and the SPADs are triggered by photons emitted by the light sources 32 as well as dark counts. The trigger events due to detected photons occur at a larger pace and the breakdown voltage monitor circuit 40 adjusts the different excess bias voltage VEX on a fast time scale (tobs2<tobs1). In this example, the negative bias voltage VHV is decreased in steps in order to increase the excess bias voltage VEX. The corresponding output signals OUTH and OUTL provide a measures whether the bias voltage VHV needs to be increases or decreases further. The stepwise adjustments (or calibration mode) may terminate when the output signals of the monitor circuit indicate that the bias voltage VHV voltage has an optimal value (e.g., when a threshold defined by reference voltages VREFH and VREFL has been reached). The observation time can be significantly reduced.

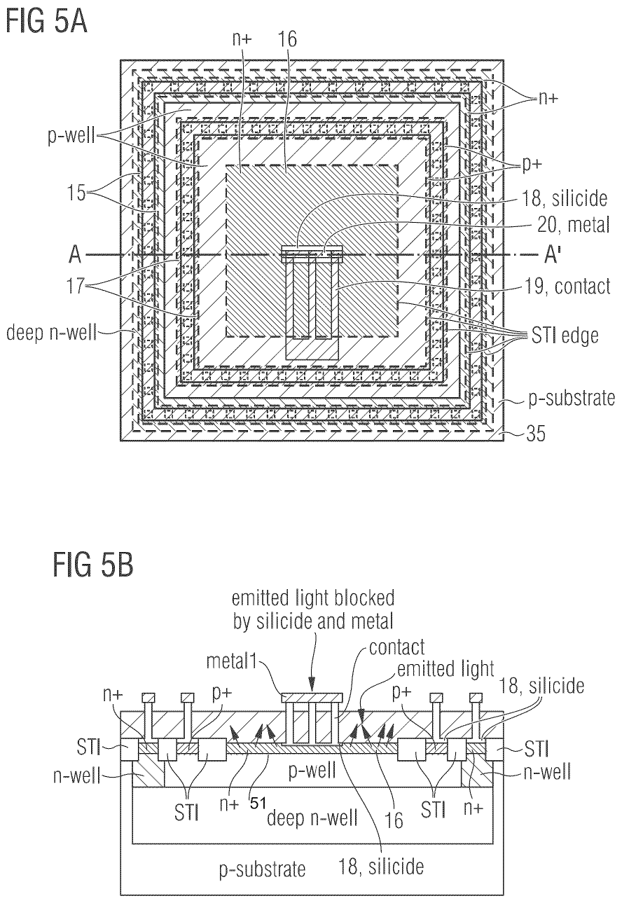

FIGS. 5A and 5B show an example layout of an integrated light source 32, e.g. a light emitting-diode with a pn-junction 51. FIG. 5A shows a top view. In the context of

FIG. 1 the depicted integrated light source 32 comprises a pn-junction 51 arranged in the bottom substrate 35. FIG. 5B shows a cross-section A-A′ as indicated in FIG. 5A. The drawings show a possible customized layout of the pn-junction 51 used to emit photons. The layout is done in a way to minimize light blocking at the backend. Therefore i.e. during fabrication, the formation of a silicide layer on top of an n+-doped region is blocked. Therefore, a silicide layer on top of an n+ doped region is only present in the vicinity of contacts 19. The n+/PW/NW structure is located in deep n-wells to minimize carrier injection into the substrate. The number and location of contacts 19 can be optimized in order to minimize routing on top of the SPAD diode 11.

In more detail, the light source 32 comprises a p-substrate (e.g., bottom substrate 35). A deep n-well is arranged into the p-substrate, e.g. as indicated in FIG. 5A by the outer dashed line. Furthermore, a p-well is arranged on a surface of the deep n-well and the p-substrate. An n-well is also arranged on said surface of the deep n-well and into the p-well. The n-well and the p-well form a common surface.

Several semiconductor regions are arranged on or into the common surface, i.e. into the n-and p-well. Several shallow trench isolations (STI) are indicated in the drawing. These STIs prevent electric current leakage between adjacent n+- and p+-doped regions. In the top view, an n+-doped region forms an outer ring 15 on the n-well and an inner region 16 on the p-well. The n+-doped region is isolated from a p+-doped region arranged on the p-well, wherein the p+-doped region forms another ring 17 on the p-well surrounded by the STIs. Yet another STI is formed to surround the outer perimeter of the n+-doped region.

The n+-doped region associated with the outer ring 15 and the p+-doped region are covered with a conducting layer 18, e.g. silicide layer in this example. The conducting layer 18 allows to contact the doped regions by way of a contact 19 and a metal 20 arranged on the respective doped regions. However, the conducting layer 18 is typically blocking light. In fact, in a standard configuration, the complete n+-doped region would be covered with the silicide layer and thus completely blocking the emission of light.

In order to prevent this and use the light source 32 to emit photons to trigger the SPADs (see FIG. 1), the n+-doped region associated with the inner region 16 is not fully covered with the conducting layer 18, i.e. an area of the inner region 16 remains free of conducting layers and, thus, does not block light (indicated by the arrows in the drawing). Furthermore, at least parts of said region are also free of metal, which else would block light as well. As can be seen from the top view of FIG. 5A an only fraction of the whole surface area of the inner region 16 is covered with the conducting layer 18 and is arranged with a contact 19 and metal. The actual size of the light emitting area can be chosen in view of the desired application. For example, in a CMOS process the conducting layer 18, e.g. the silicide layer can be partly blocked during fabrication to form the light emitting area.

The present application claims priority of the German application DE 102022117761.0, the disclosure content of which is incorpated herein by reference.

While this specification contains many specifics, these should not be construed as limitations on the scope of the invention or of what may be claimed, but rather as descriptions of features specific to particular embodiments of the invention. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous.

### REFERENCES

10 top-tier
11 avalanche diodes
12 top substrate (substrate of top-tier)
13 array of avalanche diodes
14 metallization layer of the top-tier
15 outer ring
16 inner region
17 ring
18 conducting layer
19 contact
20 metal
21 backend of line dielectrics
30 bottom-tier
31 sensor logic
32 light source, e.g. pn-junction
33 array of light sources
34 metallization layer of the bottom-tier
35 bottom substrate (substrate of bottom-tier)
36 driver circuit
37 current source
38 backend of line dielectrics
40 breakdown voltage monitor circuit
41 quenching circuit
42 comparator block
43 comparators
44 digital logic
45 control circuit
46 (quenching) transistor
50 hybrid bonding
51 pn-junction
tobs1 observation period
tobs2 observation period

1. An avalanche diode arrangement, comprising a three-dimensional integrated circuit comprising a stack with at least one top-tier and a bottom-tier, and comprising a breakdown voltage monitor circuit, wherein:
the top-tier comprises an array of avalanche diodes,
the bottom-tier comprises an array of integrated light sources implemented as light emitting diodes, located below the top-tier, and in a calibration mode of operation:
the light sources are operable to emit light towards the avalanche diodes, and
the breakdown voltage monitor circuit is operable to adjust bias voltages of the avalanche diodes depending on trigger events induced by light emitted by the light sources during the calibration mode of operation.

2. The arrangement according to claim 1, wherein the avalanche diodes are operated as single-photon avalanche diodes, SPADs.

3. The arrangement according to claim 1, wherein the array of integrated light sources comprise pn-junctions implemented in a bottom substrate of the bottom-tier.

4. The arrangement according to claim 3, wherein the pn-junctions of the light sources are formed by an n+-doped region in direct contact to a p-well.

5. The arrangement according to claim 3, wherein the pn-junctions comprise a light emitting area free of a conducting layer.

6. The arrangement according to claim 1, wherein the bottom-tier comprises a sensor logic.

7. The arrangement according to claim 1, wherein the sensor logic further comprises at least one driver circuit to provide, in the calibration mode of operation, respective forward currents to the light sources of the array of integrated light sources.

8. The arrangement according to claim 7, wherein the driver circuit comprises programmable current sources to provide the forward currents.

9. The arrangement according claim 1, wherein the top-tier and the bottom-tier are electrically interconnected by way of hybrid bonding.

10. The arrangement according to claim 1, wherein the avalanche diodes form groups in the top-tier and one light source is dedicated for each group of avalanche diodes.

11. The arrangement according to claim 1, wherein the avalanche diodes are arranged in a top substrate of the top-tier, so as to form a backside illuminated array and the top-tier is flipped so that an active surface of the avalanche diodes faces the bottom-tier.

12. The arrangement according to claim 1, wherein metallization layers are arranged in the top-tier and/or in the bottom-tier so as to guide light emitted by the light sources towards the avalanche diodes.

13. The arrangement according to claim 1, wherein the breakdown voltage monitor circuit comprises:
at least one quenching circuit for quenching of an avalanche current, at least one comparator block with two fast comparators for estimating an excess bias voltage depending on the avalanche current, and
at least one digital logic to provide output signals OUTH and OUTL to adjust a bias voltage based on the estimate of comparator block.

14. The arrangement according to claim 1, wherein a sensor logic comprises
a charge pump for generating the bias voltage VHV for the avalanche diodes, respectively, and
a digital system control for implementing a monitoring algorithm to operate the breakdown voltage monitor circuit in the calibration mode of operation.

15. The arrangement according to claim 14, wherein the digital system control is operable to control the driver circuit, such that the driver circuit activates the current sources to drive the light sources, to emit light towards the avalanche diodes in the top-tier.

16. An electronic device, comprising:
a host system, and
at least one avalanche diode arrangement according to claim 1.

17. A method for controlling an avalanche diode arrangement, in a calibration mode of operation, comprising the steps of:
using light sources implemented as light emitting diodes arranged in a bottom-tier of a stack forming a three-dimensional integrated circuit, emitting light towards an array of avalanche diodes, which are arranged in a top-tier of the stack, and
adjust bias voltages of the avalanche diodes depending on trigger events induced by light emitted by the light sources during a calibration mode of operation.
